(19) United States
(12) Patent Application Publication
(10) Pub. No.: US 2007/0231954 A1
(43) Pub. Date: Oct. 4, 2007

(54) Gold/silicon eutectic die bonding method

(76) Inventors: Kai Liu, Sunnyvale, CA (US); Ming Sun, Sunnyvale, CA (US)

Correspondence Address: FORTUNE LAW GROUP LLP, 100 CENTURY CENTER COURT, SUITE 315, SAN JOSE, CA, 95112, US

(21) Appl. No.: 11/396,404

(22) Filed: Mar. 31, 2006

(51) Int. Cl. H01L 21/00

(52) U.S. Cl. 438/106

(57) ABSTRACT

A gold/silicon eutectic die bonding method is disclosed. The method includes the steps of 1) vacuum evaporating a layer of titanium to a silicon wafer backside, the titanium layer having a thickness less than 200 Å, 2) immediately vacuum evaporating a layer of gold onto the titanium layer, the gold layer having a thickness in the range of 0.5 to 1.5 microns, 3) dicing the wafer, and 4) mounting the die onto a substrate at a eutectic temperature to form a gold/silicon eutectic alloy bond.

### BACKGROUND OF THE INVENTION

The present invention generally relates to a method of bonding a semiconductor die to a package and more particularly to a gold/silicon eutectic bonding method.

Conventional die bonding methods include a wide choice of materials that are used in the attachment of silicon dies to substrates. These materials include hard and soft solders, conductive epoxies, and gold/silicon eutectic alloys. Gold/silicon eutectic alloys are the preferred choice for small packages such as SOT563 and SOT623.

Conventional gold/silicon eutectic die bonding methods include coating the back surface of the silicon die with gold and then heating the die to a temperature above the eutectic temperature of 363° C. to form the gold/silicon eutectic alloy. In most applications, an adhesion layer of Cr and/or Ti or other sandwich type structure is used to improve the adhesion of the gold to the silicon die. The die is then attached to a metalized substrate such as a leadframe by an additional heating step which utilizes the gold/silicon eutectic alloy as a solder. Additional layers of gold may be deposited over the gold/silicon eutectic alloy layer and gold or gold alloy pre-forms may be used to facilitate die bonding. Other conventional techniques include using a gold/silicon seed as a catalyst for forming the eutectic bond and using a gold/silicon alloy produced by silicon implantation in a gold layer.

One problem associated with conventional gold/silicon eutectic die bonding methods is that gold diffuses into the silicon die leading to undesirable electrical performance of the device formed on the die. To address this problem, a barrier layer of Ti or Cr together with other metals including tungsten and platinum is usually deposited in between the back side of the silicon die and the gold layer. The barrier layer acts as a diffusion barrier which limits the amount of oxidation of the silicon and is typically about 500 Å thick. Bonding temperatures in the range of 520° C. and up are then needed to achieve eutectic bonding of the die to the substrate.

Temperatures in the range of 520° C. and up are too high for the packaging of MOSFET dies. Furthermore, the provision of adhesion and barrier layers on the die back surface is costly and reduces device throughput. There is therefore a need for a die bonding method that overcomes these problems. There is also a need for a die bonding method that utilizes a gold/silicon alloy to ensure MOSFET die attachment quality while requiring lower bonding temperatures which do not adversely affect the performance of the MOSFET devices. There is a further need for a die bonding method that is cost efficient and that increases device throughput.

### SUMMARY OF THE INVENTION

The problems associated with the bonding of MOSFETs to substrates such as leadframe substrates are solved by the gold/silicon eutectic die bonding method of the invention. It has been discovered that a thin Ti adhesion layer having a thickness less than 200 Å, and preferably between 50 Å and 150 Å, provides sufficient adhesion to the gold layer. A gold/silicon eutectic alloy bond can advantageously be formed by the application of a bonding temperature lower than 470° C., which temperature is suitable for MOSFET device assembly.

In accordance with one aspect of the invention, a gold/silicon eutectic die bonding method includes the steps of 1) vacuum evaporating a layer of titanium to a silicon wafer backside, the titanium layer having a thickness less than 200 Å, 2) immediately vacuum evaporating a layer of gold onto the titanium layer, the gold layer having a thickness in the range of 0.5 to 1.5 microns, 3) dicing the wafer, and 4) mounting the die onto a substrate at a eutectic temperature to form a gold/silicon eutectic alloy bond.

In accordance with another aspect of the invention, a gold/silicon eutectic die bonding method for bonding a MOSFET silicon die to a leadframe includes the steps of 1) grinding a silicon wafer backside comprising the MOSFET silicon die before vacuum sputtering the titanium layer, 2) vacuum evaporating a layer of titanium to the silicon wafer backside, the titanium layer having a thickness less than 200 Å, 3) immediately vacuum evaporating a layer of gold onto the titanium layer, the gold layer having a thickness in the range of 0.5 to 1.5 microns, 4) dicing the wafer, and 4) mounting the die onto the leadframe at a eutectic temperature to form a gold/silicon eutectic alloy bond.

There has been outlined, rather broadly, the more important features of the invention in order that the detailed description thereof that follows may be better understood, and in order that the present contribution to the art may be better appreciated. There are, of course, additional features of the invention that will be described below and which will form the subject matter of the claims appended herein.

In this respect, before explaining at least one embodiment of the invention in detail, it is to be understood that the invention is not limited in its application to the details of the method set forth in the following description or illustrated in the drawings. The invention is capable of other embodiments and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

These and other features, aspects and advantages of the present invention will become better understood with reference to the following drawings, description and claims.

### BRIEF DESCRIPTION OF THE DRAWINGS

FIG. 1 is a flow chart showing a gold/silicon eutectic die bonding method in accordance with the invention.

### DETAILED DESCRIPTION OF THE INVENTION

The present invention provides a gold/silicon eutectic die bonding method wherein a thin Ti adhesion layer having a thickness less than 200 Å, and preferably between 50 Å and 150 Å, provides sufficient adhesion to a gold layer adhered to a backside of a silicon wafer. A gold/silicon eutectic alloy bond which passes reliability tests such as TC 500 cycles, PCT 96 hours and HAST 100 hours, is formed by the application of a bonding temperature lower than 470° C., which temperature is suitable for MOSFET device assembly.

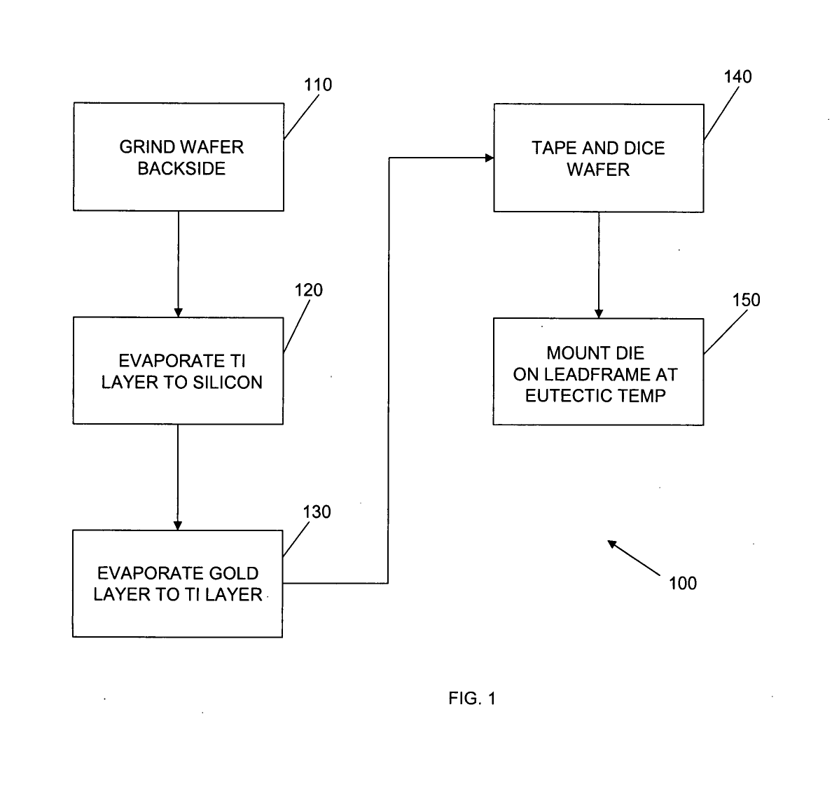

With reference to FIG. 1, the method 100 of the invention includes a step 110 in which the backside of the silicon wafer is ground to a desired thickness. In a step 120, in a vacuum environment, a 50 Å to 200 Å layer of Ti, and preferably a 50 Å to 150 Å layer of Ti, is evaporated on the backside of the wafer. The Ti layer helps to break through the SiO₂ layer formed at the surface of the silicon wafer backside and form a gold-attachable surface. Therefore, the Ti layer provides an adhesive layer between a successive gold layer and the silicon of the wafer.

Preferably the Ti layer is thin enough so that when the silicon die is heated at the die attachment stage, the silicon and gold will diffuse into each other to form the eutectic alloy. Furthermore, the Ti layer is preferably thick enough so as to avoid peeling of the gold layer from the Ti layer.

Immediately following step 120, in a step 130 a gold layer having a thickness between 0.5 microns and 1.5 microns is evaporated on the Ti layer. The wafer is then taped and diced in a step 140. Finally, in a step 150 the die are picked and mounted on a leadframe plated with silver at a temperature above the gold/silicon eutectic temperature of 370° C. and preferably between 410° C. and 470° C., depending upon the die size and bonding machine conditions.

The method 100 in accordance with the invention provides a gold/silicon eutectic die bonding method that is cost efficient and that may be performed at temperatures that do not adversely affect the performance of MOSFET devices. The method 100 further eliminates the need for the deposition of a barrier layer to thereby increase device throughput.

It should be understood, of course, that the foregoing relates to preferred embodiments of the invention and that modifications may be made without departing from the spirit and scope of the invention as set forth in the following claims.

We claim:

1. A gold/silicon eutectic die bonding method comprising the steps of:
vacuum evaporating a layer of titanium to a silicon wafer backside, the titanium layer having a thickness less than 200 Å;
immediately vacuum evaporating a layer of gold onto the titanium layer, the gold layer having a thickness in the range of 0.5 to 1.5 microns;
dicing the wafer; and
mounting the die onto a substrate at a eutectic temperature to form a gold/silicon eutectic alloy bond.

2. The gold/silicon eutectic die bonding method of claim 1, wherein the titanium layer has a thickness between 50 Å and 150 Å.

3. The gold/silicon eutectic die bonding method of claim 1, further comprising taping the wafer before dicing the wafer.

4. The gold/silicon eutectic die bonding method of claim 1, wherein the substrate comprises a silver layer.

5. The gold/silicon eutectic die bonding method of claim 1, wherein the eutectic temperature ranges from 410° C. to 470° C.

6. The gold/silicon eutectic die bonding method of claim 1, wherein the die comprise a MOSFET device.

7. The gold/silicon eutectic die bonding method of claim 1, further comprising back grinding the silicon wafer before vacuum sputtering the titanium layer.

8. A gold/silicon eutectic die bonding method for bonding a MOSFET silicon die to a leadframe comprising the steps of:
grinding a silicon wafer backside comprising the MOSFET silicon die before vacuum sputtering the titanium layer;
vacuum evaporating a layer of titanium to the silicon wafer backside, the titanium layer having a thickness less than 200 Å;
immediately vacuum evaporating a layer of gold onto the titanium layer, the gold layer having a thickness in the range of 0.5 to 1.5 microns;
dicing the wafer; and
mounting the die onto the leadframe at a eutectic temperature to form a gold/silicon eutectic alloy bond.

9. The gold/silicon eutectic die bonding method of claim 8, wherein the eutectic temperature ranges from 410° C. to 470° C.

10. The gold/silicon eutectic die bonding method of claim 8, wherein the titanium layer has a thickness between 50 Å and 150 Å.

11. The gold/silicon eutectic die bonding method of claim 8, further comprising taping the wafer before dicing the wafer.

12. The gold/silicon eutectic die bonding method of claim 8, wherein the leadframe comprises a silver layer.
